(19) United States
(12) Patent Application Publication
(10) Pub. No.: US 2023/0402816 A1
(43) Pub. Date: Dec. 14, 2023

(54) WAFER BONDING METHOD FOR TRANSFERING THIN FILMS TO A SUBSTRATE

(71) Applicant: Government of the United States of America, as represented by the Secretary of Commerce, Gaithersburg, MD (US)

(72) Inventors: Eric John Stanton, Boulder, CO (US); Nima Nader, Boulder, CO (US)

(21) Appl. No.: 18/207,731

(22) Filed: Jun. 9, 2023

Related U.S. Application Data
(60) Provisional application No. 63/351,096, filed on Jun. 10, 2022.

(51) Int. Cl. H01S 5/02; H01S 5/22

(52) U.S. Cl. CPC H01S 5/0215; H01S 5/22

(57) ABSTRACT

Embodiments of the present invention relate to a wafer bonding method for heterogenous integration of multiple wafers to a carrier substrate and bonding multiple functional wafers to the substrate to transfer semiconductor thin films. A routing layer for electrical or optical signals is defined on the substrate before a first wafer is bonded to the substrate and is optionally buried with subsequent planarization. Functional ridges are lithographically defined and etched after the first wafer is bonded to the substrate and a thin film is transferred to the substrate. A portion of the wafer surface is then cleared to expose the initial bonding surface on the substrate. A second wafer is bonded to the resulting material by etching pockets in the second functional wafer at the locations of the functional ridges from the first wafer bond.

### CROSS-REFERENCE TO RELATED APPLICATION

This application claims the benefit of priority from U.S. Provisional Patent Application Ser. No. 63/351,096, filed on Jun. 10, 2022, the disclosure of which is incorporated herein by reference in its entirety.

### STATEMENT REGARDING FEDERAL RIGHTS

The invention described herein was made with United States Government support from the National Institute of Standards and Technology (NIST), an agency of the United States Department of Commerce. The United States Government has certain rights in the invention.

### FIELD OF THE INVENTION

The present invention relates generally to fabrication of semiconductor structures, and more particularly to a process for wafer bonding.

### BACKGROUND OF THE INVENTION

Fabrication methods for photonics by heterogeneous integration typically use a multitude of small chips or dies bonded to a single silicon substrate. These dies can be made of the same material or of different materials to bring multiple functionalities to the carrier silicon substrate wafer (or carrier chip) that are not possible to be implemented directly on the carrier silicon substrate. Such materials include crystals grown on III-V substrate wafers that cannot be grown on a silicon crystal template. Materials formed by bonding these III-V chips to the silicon substrate can be integrated with other components fabricated on the silicon substrate. The silicon substrates include amorphous materials, such as silicon dioxide and silicon nitride, or crystalline materials such as silicon. The bonding interface includes the III-V material and another material that can be formed on the native silicon substrate, including silicon dioxide, silicon nitride, silicon, aluminum oxide, and the like.

Current full wafer-scale bonding methods to transfer a single thin film to a silicon substrate are limited to a single thin film transfer. Generally, the substrate on to which a film is transferred is referred to as the carrier wafer. The thin film is first prepared on a transfer wafer. Surfaces of the carrier wafer and the transfer wafer must be planar and must be very smooth to bond the wafers together. One or both of the wafers may have etched regions, but a large majority of the wafer surfaces must be at a single, higher level. The wafers are bonded, either directly or using an interlayer, and may or may not be annealed to strengthen the bond. The substrate of the transfer wafer is then removed from the bonded wafers using chemical means, mechanical means, or both. An etch stop layer that etches slower than the substrate in a certain chemical is typically used to stop the substrate removal process on this etch-stop layer. The etch stop layer is then removed, leaving the desired thin film transferred to the carrier wafer. This thin film is typically etched to expose some areas of the carrier wafer. Subsequent bonds are not possible because of the topography created from this initial thin film transfer.

Accordingly, there is a need for a fabrication process for heterogenous integration of multiple wafers to a single carrier substrate allowing for greater density of different materials bonded to the substrate.

### SUMMARY OF THE INVENTION

Embodiments of the present invention relate to a wafer bonding method for heterogenous integration of multiple wafers to a single carrier substrate allowing for greater density of different materials bonded to the substrate, and include using a silicon wafer as the primary device substrate and bonding multiple “functional” wafers to the silicon substrate to transfer semiconductor thin films. A routing layer for electrical or optical signals is defined on the silicon substrate before a first wafer is bonded to the substrate and is optionally buried with subsequent planarization. Functional ridges are lithographically defined and etched after the first wafer is bonded to the substrate and a thin film is transferred to the silicon substrate. A substantial portion of the wafer surface is then cleared of the bonded material to expose the initial bonding surface on the silicon substrate. A second wafer bonded to the resulting material by etching pockets in the second functional wafer at the locations of the functional ridges from the first wafer bond. An aligned bond will transfer the second functional layer to the silicon wafer, and this process is repeated to include additional desired functional wafers.

Accordingly, embodiments of the present invention relate to a wafer bonding method, including forming a patterned layer on a substrate layer, wherein the patterned layer comprises a conductive material and a dielectric material; planarizing the patterned layer formed by the conductive material and the dielectric material to form a planarized surface; bonding a first wafer to the planarized surface; removing a first back surface layer of the first wafer bonded to the planarized surface to expose a first etch stop layer in the first wafer; removing the first etch stop layer to expose a first device layer in the first wafer; applying a first protective mask on the first device layer in a first pattern to form a first masked portion and a first unmasked portion on the first device layer; etching the first unmasked portion on the first device layer to form a first ridge, wherein the etching the first unmasked portion of the first device layer to form the first ridge exposes the planarized surface; bonding a second wafer to the planarized surface, wherein a front surface of the second wafer comprises a pocket to receive the first ridge, wherein the pocket is positioned on the front surface of the second wafer to substantially match the location of the first ridge on the planarized surface; removing a second back surface layer of the second wafer to expose a second etch stop layer in the second wafer; removing the second etch stop layer to expose a third back surface layer of the second wafer; removing the third back surface layer of the second wafer to expose a third etch stop layer in the second wafer; removing the third etch stop layer to expose a second device layer in the second wafer; applying a second protective mask on the second device layer in a second pattern to form a second masked portion and a second unmasked portion on the second device layer; and etching the second unmasked portion of the second device layer to form a second ridge, wherein the etching the second unmasked portion of the second device layer to form the second ridge exposes the planarized surface, wherein the second ridge is formed in proximity to the first ridge on the planarized surface. In one embodiment of the present invention, the first, the second and the third back surface layers are removed using backside exposure process. In one embodiment of the present invention, the first, the second and the third etch stop layers are removed using hydrogen flouride.

Embodiments of the present invention further includes forming a first insulating layer on the first ridge and a second insulating layer on the second ridge.

In some embodiments of the present invention, the bonding the first wafer to the planarized surface includes positioning a front surface of the first wafer to face the planarized surface; aligning the front surface of the first wafer with the planarized surface; applying a first pressure to contact the front surface of the first wafer with the planarized surface at a center zone; applying a second pressure to contact the front surface of the first wafer with the planarized surface at a first annular zone; applying a third pressure to contact the front surface of the first wafer with the planarized surface at a second annular zone; and exposing the contacted front surface of the first wafer and the planarized surface to a first heat treatment, wherein the exposing the contacted front surface of the first wafer and the planarized surface to the first heat treatment bonds the front surface of the first wafer to the planarized surface.

In one aspect of the present invention, the bonding the second wafer to the planarized surface includes etching a front surface of the second wafer to form the pocket, wherein the pocket has a shape and dimensions to receive the first ridge; positioning the front surface of the second wafer to face the planarized surface; adjusting the position of the front surface of the second wafer to align the pocket formed on the second wafer to receive the first ridge on the planarized surface; applying a fourth pressure to contact the front surface of the second wafer and the planarized surface at the center zone; applying a fifth pressure to contact the front surface of the second wafer and the planarized surface at the first annular zone; applying a sixth pressure to contact the front surface of the second wafer and the planarized surface at the second annular zone; and exposing the contacted front surface of the second wafer and the planarized surface to a second heat treatment, wherein the exposing the contacted front surface of the second wafer and the planarized surface to the second heat treatment bonds the front surface of the second wafer to the planarized surface.

In one aspect of the present invention, the forming the patterned layer on the substrate layer further includes forming the dielectric layer on the substrate layer; forming a plurality of openings on the dielectric layer, wherein each of the plurality of the openings has a third pattern; and depositing the conductive material to fill the plurality of the openings formed on the dielectric layer to form the patterned layer.

In another aspect of the present invention, the forming the patterned layer on the substrate layer further includes depositing the conductive material on the substrate layer; etching the conductive material deposited on the substrate layer in a third pattern with a plurality of openings to expose a top surface of the substrate layer; and depositing the dielectric material to fill the plurality of the openings formed to expose the top surface of the surface layer to form the patterned layer.

Another embodiment of the present invention relate to a wafer bonding method, including providing a substrate layer; forming a dielectric layer on the substrate layer; forming a plurality of openings on the dielectric layer, wherein each of the plurality of the openings has a first pattern; depositing a conductive material to fill the plurality of the openings formed on the dielectric layer to form a patterned surface; planarizing the patterned surface formed by the conductive material and the dielectric layer to form a planarized surface; bonding a first wafer to the planarized surface; removing a first back surface layer of the first wafer bonded to the planarized surface to expose a first etch stop layer in the first wafer; removing the first etch stop layer to expose a first device layer in the first wafer; applying a first protective mask on the first device layer in a second pattern to form a first masked portion and a first unmasked portion on the first device layer; etching the first unmasked portion on the first device layer to form a first ridge, wherein the etching the first unmasked portion of the first device layer to form the first ridge exposes the planarized surface; forming a first insulating layer on the first ridge; bonding a second wafer to the planarized surface, wherein the bonding the second wafer to the planarized surface includes etching a front surface of the second wafer to form a pocket, wherein the pocket has a shape and dimensions to receive the first ridge; contacting the front surface of the second wafer with the planarized surface; and exposing the contacted front surface of the second wafer and the planarized surface to a first heat treatment, wherein the exposing the contacted front surface of the second wafer and the planarized surface to the first heat treatment bonds the front surface of the second wafer to the planarized surface; removing a second back surface layer of the second wafer to expose a second etch stop layer in the second wafer; removing the second etch stop layer to expose a third back surface layer of the second wafer; removing the third back surface layer of the second wafer to expose a third etch stop layer in the second wafer; removing the third etch stop layer to expose a second device layer in the second wafer; applying a second protective mask on the second device layer in a third pattern to form a second masked portion and a second unmasked portion on the second device layer, etching the second unmasked portion of the second device layer to form a second ridge, wherein the etching the second unmasked portion of the second device layer exposes the planarized surface, wherein the second ridge is formed in proximity to the first ridge on the planarized surface; and forming a second insulating layer on the second ridge. In one embodiment of the present invention, the first, the second and the third back surface layers are removed using backside exposure process. In another embodiment of the present invention, the first, the second and the third etch stop layers are removed using hydrogen flouride.

In one aspect of the present invention, the bonding the first wafer to the planarized surface includes positioning a front surface of the first wafer to face the planarized surface; aligning the front surface of the first wafer with the planarized surface; applying a first pressure to contact the front surface of the first wafer with the planarized surface at a center zone; applying a second pressure to contact the front surface of the first wafer with the planarized surface at a first annular zone; applying a third pressure to contact the front surface of the first wafer with the planarized surface at a second annular zone; and exposing the contacted front surface of the first wafer and the planarized surface to a second heat treatment, wherein the exposing the contacted front surface of the first wafer and the planarized surface to the second heat treatment bonds the front surface of the first wafer to the planarized surface.

In one embodiment of the present invention, the first and the second heat treatment comprises a thermal annealing.

In another aspect of the present invention, the contacting the front surface of the second wafer with the planarized surface includes positioning the front surface of the second wafer to face the planarized surface; adjusting the position of the front surface of the second wafer to align the pocket formed on the second wafer to receive the first ridge formed on the planarized surface; applying a fourth pressure to contact the front surface of the second wafer and the planarized surface at the center zone; applying a fifth pressure to contact the front surface of the second wafer and the planarized surface at the first annular zone; and applying a sixth pressure to contact the front surface of the second wafer and the planarized surface at the second annular zone.

Embodiments of the present invention also relate to a wafer bonding method, including forming a patterned layer on a substrate layer, wherein the patterned layer comprises a conductive material and a dielectric material; planarizing the patterned layer formed by the conductive material and the dielectric material to form a planarized surface; bonding a first wafer to the planarized surface, wherein the bonding the first wafer to the planarized surface includes positioning a front surface of the first wafer to face the planarized surface; aligning the front surface of the first wafer with the planarized surface; contacting the front surface of the first wafer with the planarized surface; and exposing the contacted front surface of the first wafer and the planarized surface to a first thermal annealing, wherein the exposing the contacted front surface of the first wafer and the planarized surface to the first thermal annealing bonds the front surface of the first wafer to the planarized surface; removing a first back surface layer of the first wafer bonded to expose a first etch stop layer in the first wafer; removing the first etch stop layer to expose a first device layer in the first wafer; applying a first protective mask on the first device layer in a first pattern to form a first masked portion and a first unmasked portion on the first device layer; etching the first unmasked portion on the first device layer to form a first ridge, wherein the etching the first unmasked portion of the first device layer to form the first ridge exposes the planarized surface; forming a first insulating layer on the first ridge; bonding a second wafer to the planarized surface, wherein the bonding the second wafer to the planarized surface includes etching a front surface of the second wafer to form a pocket, wherein the pocket has a shape and dimensions to receive the first ridge, wherein the pocket is positioned on the front surface of the second wafer to substantially match the location of the first ridge formed on the planarized surface; positioning the front surface of the second wafer to face the planarized surface; adjusting the position of the front surface of the second wafer to align the pocket formed on the second wafer to receive the first ridge formed on the planarized surface; contacting the front surface of the second wafer and the planarized surface; and exposing the contacted front surface of the second wafer and the planarized surface to a second thermal annealing, wherein the exposing the contacted front surface of the second wafer and the planarized surface to the second thermal annealing bonds the front surface of the second wafer to the planarized surface; removing a second back surface layer of the second wafer bonded to expose a second etch stop layer in the second wafer; removing the second etch stop layer to expose a third back surface layer of the second wafer; removing the third back surface layer of the second wafer to expose a third etch stop layer in the second wafer; removing the third etch stop layer to expose a second device layer in the second wafer; applying a second protective mask on the second device layer in a second pattern to form a second masked portion and a second unmasked portion on the second device layer; etching the second unmasked portion of device layer to form a second ridge, wherein the etching the second unmasked portion of the second device layer exposes the planarized surface, wherein the second ridge is formed in proximity to the first ridge on the planarized surface; and forming a second insulating layer on the second ridge. In one embodiment of the present invention, the first, the second and the third back surface layers are removed using backside exposure process. In another embodiment of the present invention, the first, the second and the third etch stop layers are removed using hydrogen fluoride.

In one aspect of the present invention, the forming the patterned layer on the substrate layer further includes forming the dielectric layer on the substrate layer; forming a plurality of openings on the dielectric layer, wherein each of the plurality of the openings has a third pattern; and depositing the conductive material to fill the plurality of the openings formed on the dielectric layer to form the patterned layer.

In another aspect of the present invention, the forming the patterned layer on the substrate layer further includes depositing the conductive material on the substrate; etching the conductive material deposited on the substrate layer in a third pattern with a plurality of openings to expose a top surface of the substrate layer; and depositing a dielectric material to fill the plurality of the openings formed to expose the top surface of the surface layer to form the patterned layer.

### BRIEF DESCRIPTION OF DRAWINGS

FIGS. 1A-1N illustrate side cross-sectional views of a wafer bonding method in accordance with embodiments of the present invention.

FIGS. 2A-2G illustrate an exemplary schematic representation of a wafer bonding method in accordance with embodiments of the present invention.

FIGS. 3A-3K illustrate side cross-sectional views of an exemplary wafer bonding method in accordance with embodiments of the present invention as shown in FIGS. 2A-2G.

### DETAILED DESCRIPTION

While the making and using of various embodiments of the present invention are discussed in detail below, it should be appreciated that the present invention provides many applicable inventive concepts which can be embodied in a wide variety of specific contexts. The specific embodiments discussed herein are merely illustrative of specific ways to make and use the invention, and do not delimit the scope of the present invention. Reference will be made to the drawings wherein like numerals refer to like elements throughout.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of“above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” or “wafer” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, and the like. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Wafer bonding method for heterogenous integration of multiple wafers to a single carrier substrate allowing for greater density of different materials bonded to the substrate, as described herein, can include a silicon wafer as the primary device substrate, and multiple functional wafers bonded to the silicon substrate to transfer semiconductor thin films. A routing layer for electrical or optical signals is defined on the silicon substrate before a first wafer is bonded to the substrate and is optionally buried with subsequent planarization. Functional ridges are lithographically defined and etched after the first wafer is bonded to the substrate and a thin film is transferred to the silicon substrate. The functional ridges provide electrical or optical functionality, or both, that is optionally connected to a previously defined routing layer on the silicon substrate. A substantial portion of the wafer surface is then cleared of the bonded material to expose the initial bonding surface on the silicon substrate. A second wafer is bonded to the resulting material by etching pockets in the second functional wafer at the locations of the functional ridges from the first wafer bond. The etched pockets will enable a void-free second wafer bond by avoiding extra surface topography introduced by the first bonding step. An aligned bond will transfer the second functional layer to the silicon wafer, and this process is repeated to include additional desired functional wafers.

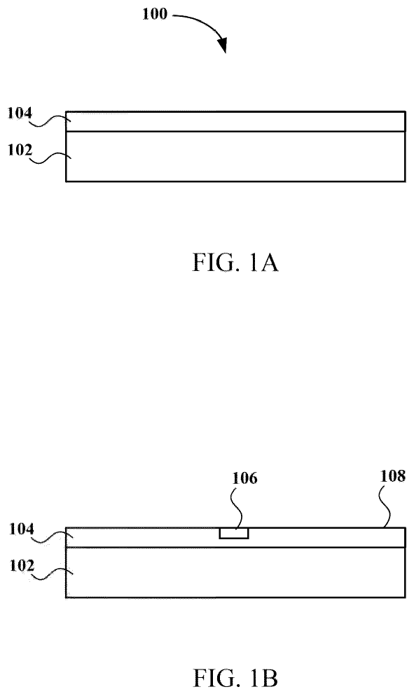

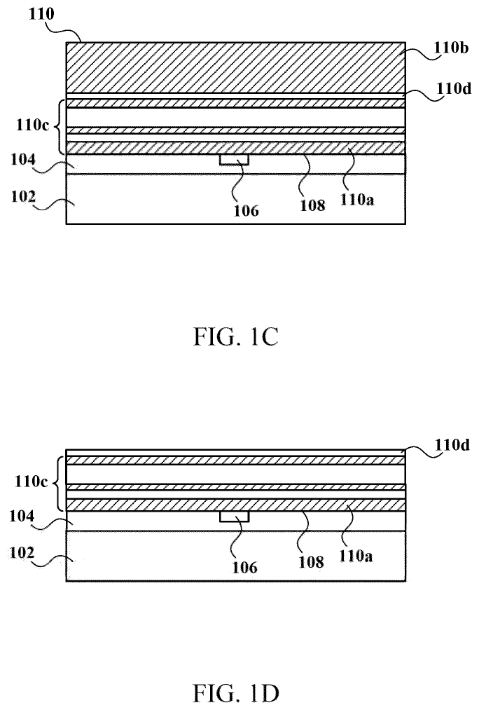

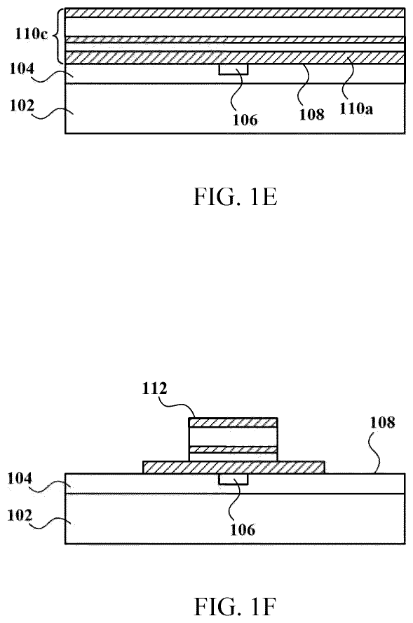

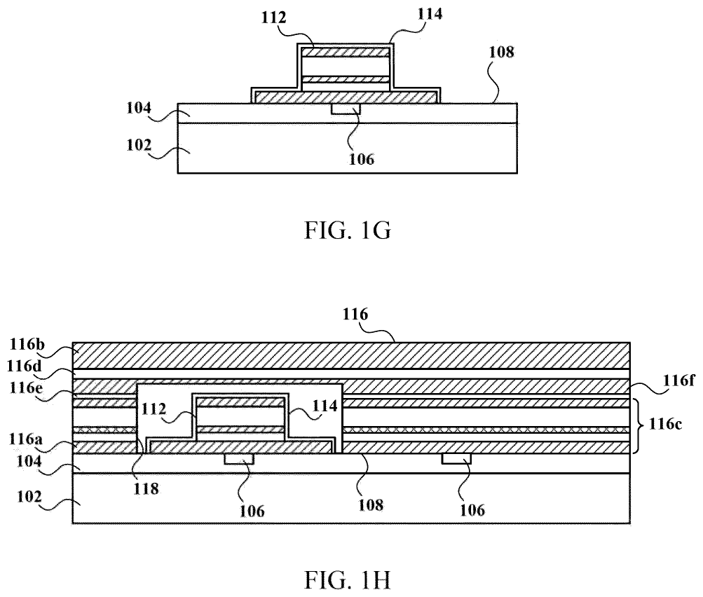

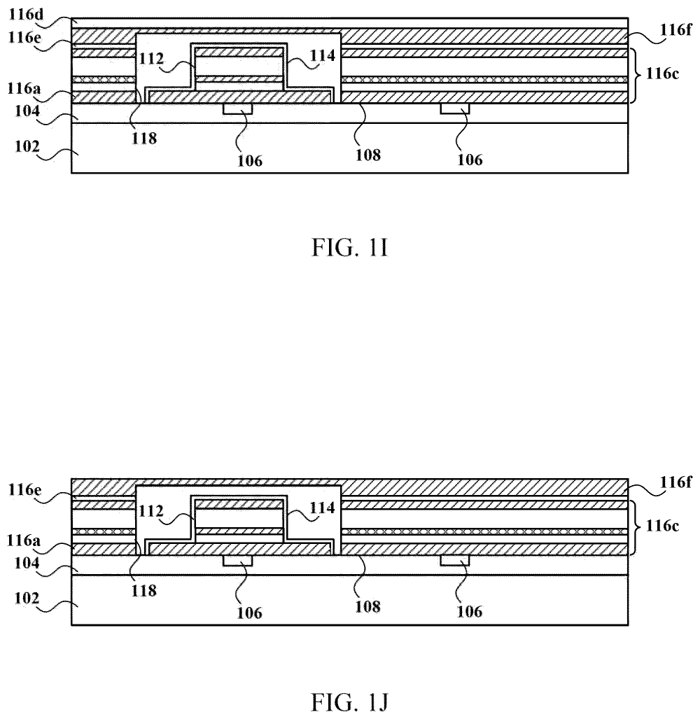

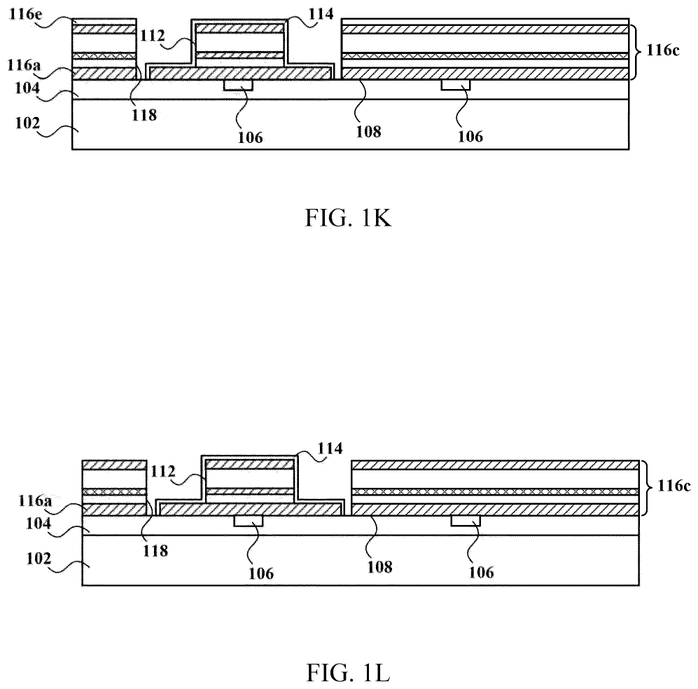

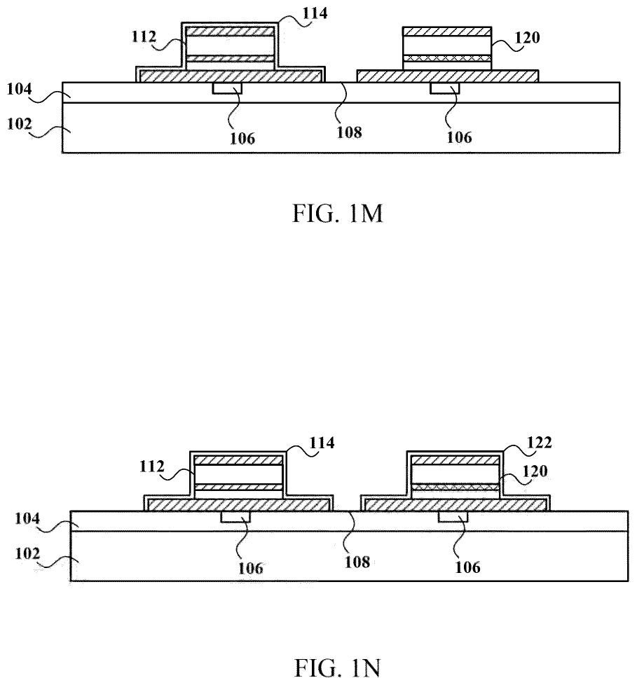

Referring now to the drawings, and more particularly, to FIGS. 1A-1N, there is shown a wafer bonding method, generally designated 100 and schematically showing an embodiment of the present invention, for transferring a plurality of thin films to a substrate. FIGS. 1A-1N illustrate side cross-sectional views of wafer bonding method 100 in accordance with embodiments of the present invention.

As shown in FIG. 1A, a dielectric layer 104 is formed on top surface of substrate 102. Exemplary dielectric material include glass, silicon dioxide, silicon nitride, sapphire, and the like. Fabrication methods to form the dielectric layer include, but not limited to, lithography, etching, deposition, filling, polishing, or a combination thereof. Openings having a predetermined depth may be formed in a desired pattern on dielectric layer 104. Openings may be formed on dielectric layer 104 by any technique known in the art, including but not limited to imprinting, sand blasting, laser drilling, etching, and the like. A conductive material 106 may then be deposited to fill the openings formed on dielectric layer 104, as shown in FIG. 1B. In one embodiment of the present invention, conductive material 106 is capable of conducting electrical signals. Exemplary conductive material 106 capable of conducting electrical signals include aluminum, gold, titanium, copper, platinum, palladium, and the like. In another embodiment of the present invention, conductive material 106 is capable of transmitting optical signals. Exemplary conductive material 106 capable of transmitting optical signals include silicon, silicon nitride, tantalum pentoxide, germanium, lithium niobate, aluminum nitride, gallium arsenide, indium phosphide, and the like. The patterned surface formed by conductive material 106 and dielectric layer 104 may then be planarized to form a planarized surface 108, as shown in FIG. 1B. Exemplary planarization techniques that can be used include chemical mechanical polishing, wet chemical cleaning, or a combination thereof.

In an alternate method in accordance with embodiments of the present invention, conductive material 106 is deposited on first surface of substrate 102. A routing layer is formed by etching conductive material 106 deposited on substrate 102 in a desired pattern with openings to expose the top surface of substrate 102. Routing layer and the exposed top surface of substrate 102 may be substantially covered with a dielectric layer 104, which may be planarized to form planarized surface 108.

After the formation of planarized surface 108, wafer bonding method 100 proceeds to bonding a first wafer 110 to planarized surface 108 for transferring a film to substrate 102, as shown in FIG. 1C. In some embodiments, first wafer 110 can include silicon (e.g., monocrystalline silicon, polycrystalline silicon), germanium, a III-V semiconductor, silicon carbide, silicon on insulating substrate, silicon germanium (SiGe), gallium arsenide (GaAs), germanium (Ge), silicon on insulator (SOI), germanium on insulator (GOI), indium gallium arsenide (InGaAs), aluminum gallium arsenide (AlGaAs), or any suitable combination thereof. First wafer 110 can include a front surface layer 110a for bonding with planarized surface 108 and a back surface layer 110b. Front surface layer 110a can include substrate layers and a back surface layer 110b can include dielectric layers. In some embodiments, substrate layers forming front surface layer 110a and back surface layer 110b of first wafer 110 can include dielectric layers of oxides, nitrides, carbides or a combination thereof. In some embodiments, front surface layer 110a and back surface layer 110b of first wafer 110 can include SiO₂, Si₃N₄, or a nitrogen-doped silicon carbide. In one embodiment of the present invention, back surface layer 110b includes a dielectric layer 110d as a top layer that has a substantially greater thickness than layers in between the layers forming front surface layer 110a and back surface layer 110b. In an exemplary embodiment of the present invention, back surface layer 110b is a GaAs layer having a thickness of about 625,000 nm.

First wafer 110 also includes a device layer 110c formed by multiple layers of thin films of II-V semiconductors and at least one etch stop layer 110d that can be included in between layers forming front surface layer 110a and back surface layer 110b, as further shown in FIG. 1C. An etch stop layer 110d is disposed between back surface layer 110b and device layer 110c of first wafer 110. Exemplary materials for etch stop layer 110d can include Al_{0.80}Ga_{0.20}As and In_{0.49}Ga_{0.51}P.

First wafer 110 and planarized surface 108 are positioned in parallel and face to face with each other, with front surface layer 110a of first wafer 110 facing towards planarized surface 108. In some embodiments, a preliminary alignment process can also be performed. In the preliminary alignment process, position of first wafer 110 can be adjusted such that the centers of first wafer 110 and planarized surface 108 are substantially aligned. A center zone of first wafer 110 can be pressed in a downward direction by applying a first pressure to bring first wafer 110 and planarized surface 108 into contact at center zone and initiate the bonding process. A second pressure can be applied at a first outer annular zone of first wafer 110 and planarized surface 108 to bring first outer annular zone of first wafer 110 and planarized surface 108 into contact. A third pressure can also be applied at a second outer annular zone of first wafer 110 and planarized surface 108 to bring first wafer 110 and planarized surface 108 into full contact.

After preliminary alignment and contacting of first wafer 110 and planarized surface 108, wafer bonding method 100 proceeds to a heat treatment performed on first wafer 110 and planarized surface 108 to bond front surface layer 110a of first wafer 110 to planarized surface 108. In some embodiments, the heat treatment can include thermally annealing of first wafer 110 and planarized surface 108 after preliminary bonding. The preliminary bonded first wafer 110 and planarized surface 108 are thermally annealed under nitrogen atmosphere, with an annealing temperature between about 200 deg. C. and 450 deg. C. In one embodiment, the heat treatment time is between about 1 hour and 2 hours. In some embodiments, the preliminary bonded first wafer 110 and planarized surface 108 are thermally annealed under nitrogen atmosphere, at an annealing temperature of about 200 deg. C. for about 2 hours. In some embodiments, the preliminary bonded first wafer 110 and planarized surface 108 are thermally annealed under nitrogen atmosphere, at an annealing temperature of about 280 deg. C. for about 1 hour. In some embodiments, the preliminary bonded first wafer 110 and planarized surface 108 can be thermally annealed under nitrogen atmosphere at an annealing temperature of about 350 deg. C. for about 2 hours. In some embodiments, the preliminary bonded first wafer 110 and planarized surface 108 are thermally annealed under nitrogen atmosphere at an annealing temperature of about 400 deg. C. for about 1 hour. In some embodiments, the above-mentioned wafer bonding process can be performed using an automated bond alignment system. In some embodiments, condensation reactions of silanol groups on front surface layer 110a of first wafer 110 and top surface 108a of planarized surface 108 can occur during the heat treatment which results in Si—O—Si bond formations between the abovementioned front surfaces. In addition, the formation of condensation reaction can also generate H₂O molecules. In other embodiments, the heat treatment forms a plurality of covalent bonds between front surface layer 110a of first wafer 110 and top surface 108a of planarized surface 108. In some embodiments, the covalent bond is Si—O—Si. In some embodiments, the covalent bond has a bond strength of at least 2.0 J/m². In one embodiment, the covalent bond has a bond strength greater than 2.0 J/m². Bonding first wafer 110 to planarized surface 108 may also be performed using any known techniques in the art including, but not limited to, adhesive bonding, anodic bonding, eutectic bonding, fusion bonding, glass frit bonding, hybrid bonding, solid-liquid inter-diffusion bonding, and the like.

After bonding of first wafer 110 to planarized surface 108, wafer bonding method 100 proceeds to an operation for selective removal of back surface layer 110b of first wafer 110 to form a structure as shown in FIG. 1D. Selective removal of back surface layer 110b can be performed using a process referred to as a backside exposure process. An etchant may also be used to remove back surface layer 110b until etch stop layer 110d is exposed, as shown in FIG. 1D, and the exposed etch stop layer 110d is removed to expose device layer 110c, as shown in FIG. 1E. In one embodiment, etch stop layer 110d is removed using hydrogen fluoride. In embodiments including an etch stop layer in the multilayer substrate, backgrinding may be performed to access etch stop layer 110d, and then a wet etch and/or polishing process may be performed until the etch/polishing effectively stops at etch stop layer 110d. In other embodiments including a fast etch layer in a multilayer substrate, a lateral wet etch may be performed to remove the fast etch layer and allow release of the bulk wafer from the device quality layer (a lift-off process, rather than a grinding process). In other embodiments, the multilayer substrate may include a fast etch layer and an etch stop layer. In some such embodiments, a lateral etch may be performed to release the bulk wafer, and then a backside etch and/or polish may be performed until the etch/polish effectively stops at etch stop layer 110d.

After bonding of first wafer 110 to planarized surface 108 followed by selective removal of back surface layer 110b of first wafer 110 and removal of etch stop layer 110d to expose device layer 110c, wafer bonding method 100 proceeds to an operation for forming a functional ridge 112 from device layer 110c, as shown in FIG. 1F. Ridge 112 on device layer 110c may be lithographically defined by applying a protective mask to the device layer in a predetermined pattern to form a masked portion and an unmasked portion of the device layer and then formed by etching away unmasked portion of device layer 110c to expose planarized surface 108. In one embodiment of the present invention, ridge 112 formed from device layer 110c are laser ridges. Ridge 112 provides electrical or optical functionality that may be connected to a previously defined routing layer on a silicon substrate.

In order to protect ridge 112 formed on device layer 110c and preserve ridge 112 surface from subsequent bonding, wafer bonding method 100 proceeds to an operation for forming an insulating protective layer 114 on the top surface of ridge 112 formed from device layer 110c, as shown in FIG. 1G. Insulating layers 114 can be deposited and patterned using any technique known in the art including. Exemplary techniques to deposit insulating layers 114 include sputtering and electron-beam evaporation, and the like. Exemplary techniques for patterning insulating layers 114 include photolithography and electron beam lithography using a lift-off process, and the like. In one embodiment of the present invention, ridge 112 can be protected by forming a SiN insulating layer using a lift-off of electron-beam deposition.

After the formation of ridge 112 and protecting with insulating layer 114, wafer bonding method 100 proceeds to bonding a second wafer 116 to first wafer 110, as shown in FIG. 1H. Second wafer 116 includes a front surface layer 116a, a back surface layer 116b, and a device layer 116c formed by multiple layers of thin films of III-V semiconductors. Etch stop layers 116d and 116e can be included in between layers forming front surface layer 116a and back surface layer 116b, as shown in FIG. 1H. Etch stop layer 116d is disposed between back surface layer 110b and a substrate layer 116f and etch stop layer 116e is disposed between substrate layer 116f and device layer 116c to protect ridge 112 during fabrication methods performed to form ridge 120 (shown in FIG. 1M) from device layer 116c of second wafer 116.

Front surface layer 116a is etched to form pocket 118 having a shape and dimensions to receive ridge 112 formed on planarized surface 108. In one embodiment, pocket 118 has shape and dimensions to receive ridge 112 with substantial clearance between surfaces of pocket 118 and ridge 112 with insulating layer 114. Pocket 118 is positioned on front surface layer 116a to substantially match the location of ridge 112 formed on planarized surface 108. Pocket 118 will enable a void-free bond with second wafer 116 by avoiding the surface topography introduced by the bonding of first wafer 110 to planarized surface 108.

Second wafer 116 and planarized surface 108 are positioned in parallel and face to face with each other, with front surface layer 116a of second wafer 116 facing towards top surface 108a of planarized surface 108. In some embodiments, a preliminary alignment process can also be performed. In the preliminary alignment process, position of second wafer 116 can be adjusted such that the centers of second wafer 116 and planarized surface 108 are substantially aligned and pocket 118 is positioned to receive ridge 112. A center zone of second wafer 116 can be pressed in a downward direction by applying a first pressure to bring second wafer 116 and planarized surface 108 into contact at center zone and initiate the bonding process. A second pressure can be applied at a first outer annular zone of second wafer 116 and planarized surface 108 to bring first outer annular zone of second wafer 116 and planarized surface 108 into contact. A third pressure can also be applied at a second outer annular zone of second wafer 116 and planarized surface 108 to bring second wafer 116 and planarized surface 108 into full contact.

After preliminary alignment and contacting of second wafer 116 and planarized surface 108, wafer bonding method 100 proceeds to a heat treatment performed on second wafer 116 and planarized surface 108 to bond front surface layer 116a of second wafer 116 to top surface 108a of planarized surface 108. In some embodiments, the heat treatment can include thermally annealing second wafer 116 and planarized surface 108 after preliminary bonding. The preliminary bonded second wafer 116 and planarized surface 108 are thermally annealed under nitrogen atmosphere, with an annealing temperature between about 200 deg. C. and 450 deg. C. In some embodiments, the heat treatment time is between about 1 hour and 2 hours. In some embodiments, the heat treatment forms a plurality of covalent bonds between front surface layer 116a of second wafer 116 and top surface 108a of planarized surface 108. In some embodiments, the covalent bond is Si—O—Si. In some embodiments, the covalent bond has a bond strength of at least 2.0 J/m². In some embodiments, the covalent bond has a bond strength greater than 2.0 J/m².

After bonding of second wafer 116 to planarized surface 108, wafer bonding method 100 proceeds to an operation for selective removal of back surface layer 116b of second wafer 116 to form a structure as shown in FIG. 1I. Selective removal of back surface layer 116b can be performed using backside exposure process. Back surface layer 116b is removed until etch stop layer 116d is exposed, as shown in FIG. 1I. In embodiments including an etch stop layer in the multilayer substrate, backgrinding may be performed to access etch stop layer 110d, and then a wet etch and/or polishing process may be performed until the etch/polishing effectively stops at etch stop layer 116d. In other embodiments including a fast etch layer in a multilayer substrate, a lateral wet etch may be performed to remove the fast etch layer and allow release of the bulk wafer from the device quality layer (a lift-off process, rather than a grinding process). In other embodiments, the multilayer substrate may include a fast etch layer and an etch stop layer. In some such embodiments, a lateral etch may be performed to release the bulk wafer, and then a backside etch and/or polish may be performed until the etch/polish effectively stops at the etch stop layer. After back surface layer 116b is removed to expose etch stop layer 116d, etch stop layer 116d is removed using a chemical process to expose substrate layer 116f, as shown in FIG. 1J. Substrate 116f is then removed until etch stop layer 116e is exposed, as shown in FIG. 1K, and the exposed etch stop layer 116e is removed to expose device layer 116c, as shown in FIG. 1L. In one embodiment, etch stop layers 116d and 116e are removed using hydrogen fluoride.

After bonding of second wafer 116 to planarized surface 108 followed by selective removal of back surface layer 116b of second wafer 116, etch stop layer 116d, substrate layer 116f and etch stop layer 116e, wafer bonding method 100 proceeds to an operation for forming a functional ridge 120 from device layer 116c on planarized surface 108, as shown in FIG. 1M. Ridge 120 may be lithographically defined by applying a protective mask to the device layer in a predetermined pattern to form a masked portion and an unmasked portion of the device layer and then formed by etching away unmasked portion of device layer 116c to expose planarized surface 108. In one embodiment of the present invention, ridge 120 formed on planarized surface 108 are laser ridges. Ridge 120 provides electrical or optical functionality that may be connected to a previously defined routing layer on a silicon substrate.

Ridge 120 may be formed in close proximity to ridge 112 allowing for greater density of functional ridges formed on a single substrate. The distance between ridges 112 and 120 depends on alignment accuracy when aligning pocket 118 over ridge 120. Pocket 118 must be larger than ridge 120 by a distance that is substantially equal to alignment accuracy provided by wafer bonding tools. This alignment inaccuracy dictates the minimum distance between functional ridges or devices added to the substrate from different wafers. In an exemplary embodiment, the distance between ridges 112 and 120, or the pitch, is about 4 microns.

In order to protect ridge 120 formed from device layer 116c and preserve ridge 120 surface from subsequent bonding, wafer bonding method 100 proceeds to an operation for forming an insulating protective layer 122 on the top surface of ridge 120 formed on device layer 116c, as shown in FIG. 1N. Insulating layer 122 can be deposited and patterned using any technique known in the art. Exemplary techniques to deposit insulating layers 122 include sputtering and electron-beam evaporation, and the like. Exemplary techniques to for patterning insulating layers 122 include photolithography and electron beam lithography (for patterning) using a lift-off process, and the like. In one embodiment of the present invention, ridge 120 formed on device layer 116c can be protected by forming a SiN insulating layer with a lift-off of electron-beam deposition. Additional functional ridges may be formed on planarized surface 108 by following the operation described herein for forming ridge 120.

Reference now to the specific examples which follow will provide a clearer understanding of methods in accordance with embodiments of the present invention. The examples should not be construed as a limitation upon the scope of the present invention.

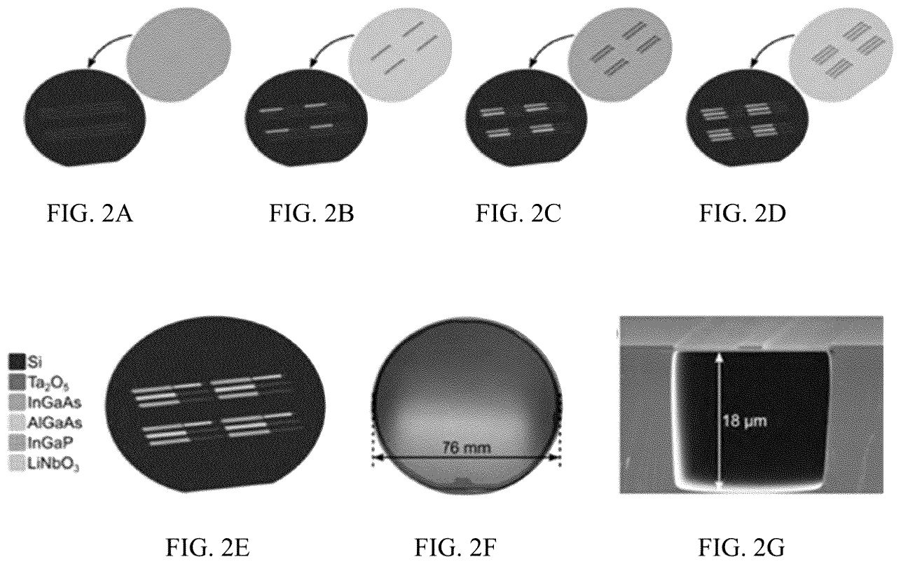

FIGS. 2A-2G illustrate an exemplary fabrication process for aligned multi-wafer-bonding. A wafer including quantum well (QW) gain material, such as InGaAs, is first bonded to a Si substrate with Ta₂O₅ waveguides deposited on the Si substrate and buried with subsequent planarization, as shown in FIG. 2A. Back surface of the bonded wafer is removed using a backside exposure process and the InGaAs QW gain material bonded to the Si substrate is etched into ridges over the Ta₂O₅ waveguides. The etching to form ridges exposes the Si substrate and the remaining waveguides in the Si substrate. Additional wafers are sequentially bonded to the exposed Si substrate and etched into ridges, as shown in FIGS. 2B, 2C and 2D and 2(d). Prior to bonding each wafer on to the exposed Si substrate, pockets are etched into each wafer front surface at locations to match the locations and patterns of the ridges already formed on the Si substrate, as further shown in FIGS. 2B, 2C and 2D. Back surface of each of the additional bonded wafer is removed using the backside exposure process and the InGaAs QW gain material bonded to the Si substrate is etched into ridges over the Ta₂O₅ waveguides. The etching to form ridges exposes the Si substrate for the subsequent wafer bonding and exposes any remaining waveguides in the Si substrate for placement of subsequent ridges over these waveguides. FIG. 2E illustrates a schematic representation of the final wafer formed and having ultra-broadband gain and nonlinear materials. FIG. 2F illustrates an example of a 3-inch wafer having III-V film bonded to Si with >99% area yield, and FIG. 2G illustrates an example of a bonded large trench or pocket.

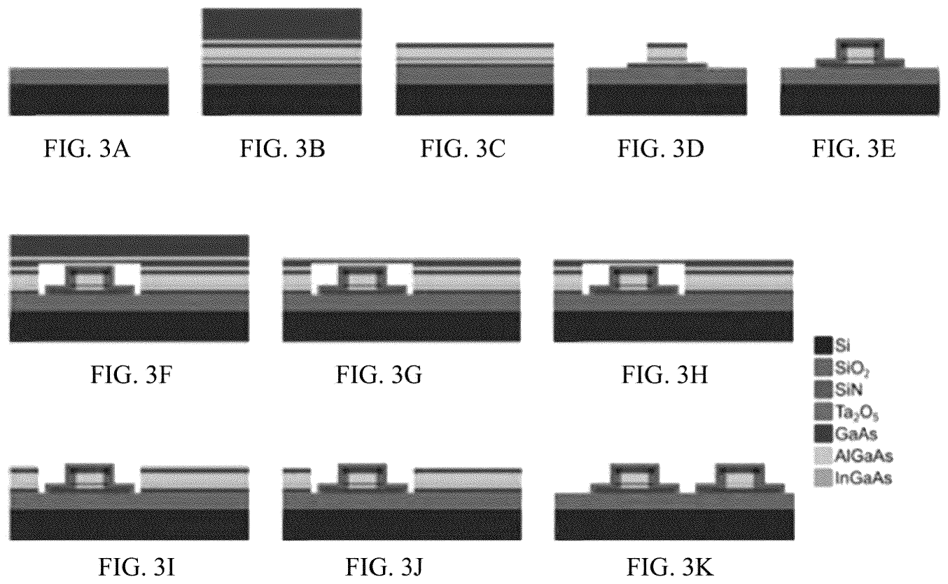

FIGS. 3A-3K illustrate cross-sectional views of an exemplary multi-wafer III-V integration. A Ta₂O₅ waveguide is deposited on a Si substrate, etched, and planarized with SiO₂, as shown in FIG. 3A. The first laser gain material is bonded to the planarized surface, as shown in FIG. 3B. The first laser gain material includes GaAs, AlGaAs and InGaAs arranged in layers, as shown in FIG. 3B, and includes an AlGaAs etch-stop layer positioned between the back surface formed by GaAs substrate and the remaining layers. The back surface formed by GaAs substrate is selectively removed using backside exposure process until the AlGaAs etch-stop layer is exposed and followed by the removal of the AlGaAs etch-stop layer to form the structure as shown in FIG. 3C. The laser ridge and n-contact layers formed by GaAs, AlGaAs and InGaAs are then lithographically defined and etched, as shown in FIG. 3D. A SiN insulation layer is formed over the laser ridge (FIG. 3E) with a lift-off of electron-beam deposition to protect the laser ridges and preserve the SiO2 surface for subsequent bonds. Etching to form the laser ridge exposes the planarized surface for subsequent bonding of additional wafers. A second laser gain material with an etched pocket to fit over the first laser ridge is bonded to the planarized surface, as shown in FIG. 3F. The second laser ridge is formed by GaAs, AlGaAs and InGaAs arranged in layers, as shown in FIG. 3F, and includes a first AlGaAs etch-stop layer positioned between the back surface formed by GaAs substrate and the remaining layers and a second AlGaAs etch-stop layer positioned above the top layer of the layers forming the laser ridge, as further shown in FIG. 3F. Dual etch-stop layers are necessary to protect the previously-defined laser ridges. The back surface formed by GaAs substrate is selectively removed using backside exposure process until the first AlGaAs etch-stop layer is exposed, as shown in FIG. 3G, and followed by the removal of the AlGaAs etch-stop layer using hydrogen fluoride to form the structure shown in FIG. 3H. The GaAs substrate layer formed above the second AlGaAs etch-stop layer is also removed by dry etching to form the structure shown in FIG. 3I. The second AlGaAs etch-stop layer is also removed using hydrogen fluoride to expose the second laser gain materials, as shown in FIG. 3I. The laser ridge formed by GaAs, AlGaAs and InGaAs layers are then lithographically defined and etched, and a SiN insulation layer is formed over the laser ridge, as shown in FIG. 3K, to protect the laser ridges and preserve the SiO₂ surface for subsequent bonds.

It should be understood that operations shown in wafer bonding method 100 and the exemplary fabrication methods shown in FIGS. 2A-2G and 3A-3K are not exhaustive and that other methods and operations can be performed as well before, after, or between any of the illustrated methods and operations.

Wafer bonding method 100 in accordance with embodiments of the present invention has several advantages over previous wafer bonding methods. Wafer bonding method 100 in accordance with embodiments of the present invention provides heterogeneous integration of electronic, photonic, or magnetic technologies with high density, a fabrication process to bond multiple wafers to a single carrier substrate, and allows for a wide range of laser wavelengths integrated on a single chip with functionality to route, modulate, and detect light. Wafer bonding method 100 can be utilized for chip-scale driving of atomic optical lattice clocks and for quantum entangled light sources. Wafer bonding method 100 including the operation of etching pockets in the functional wafers following the first wafer bond allows for wafer bonding to contact the same surface of the carrier wafer in multiple instances. This further allows for integration of different functional materials in close proximity and on the same planar level. The use of two etch-stop layers in the functional wafers following the first bond allows for a non-destructive substrate removal process and prevents damage to the existing functional ridges. This also allows for the pockets to be etched deep enough to completely encapsulate the existing ridges. Wafer bonding method 100 in accordance with embodiments of the present invention is faster and less expensive to implement and allows for much greater density of different materials bonded to the silicon substrate and interleaving of the different bonded materials without additional effort.

Wafer bonding method 100 in accordance with one or more embodiments of the present invention can be adapted to a variety of configurations. It is thought that wafer bonding method in accordance with various embodiments of the present invention and many of its attendant advantages will be understood from the foregoing description and it will be apparent that various changes may be made without departing from the spirit and scope of the invention or sacrificing all of its material advantages, the form hereinbefore described being merely a preferred or exemplary embodiment thereof.

Those familiar with the art will understand that embodiments of the invention may be employed, for various specific purposes, without departing from the essential substance thereof. The description of any one embodiment given above is intended to illustrate an example rather than to limit the invention. This above description is not intended to indicate that any one embodiment is necessarily preferred over any other one for all purposes, or to limit the scope of the invention by describing any such embodiment, which invention scope is intended to be determined by the claims, properly construed, including all subject matter encompassed by the doctrine of equivalents as properly applied to the claims.

1. A wafer bonding method, said method comprising:
forming a patterned layer on a substrate layer, wherein the patterned layer comprises a conductive material and a dielectric material;
planarizing the patterned layer formed by the conductive material and the dielectric material to form a planarized surface;
bonding a first wafer to the planarized surface;
removing a first back surface layer of the first wafer bonded to the planarized surface to expose a first etch stop layer in the first wafer;
removing the first etch stop layer to expose a first device layer in the first wafer;
applying a first protective mask on the first device layer in a first pattern to form a first masked portion and a first unmasked portion on the first device layer;
etching the first unmasked portion on the first device layer to form a first ridge, wherein the etching the first unmasked portion of the first device layer to form the first ridge exposes the planarized surface;
bonding a second wafer to the planarized surface, wherein a front surface of the second wafer comprises a pocket to receive the first ridge, wherein the pocket is positioned on the front surface of the second wafer to substantially match the location of the first ridge on the planarized surface;
removing a second back surface layer of the second wafer to expose a second etch stop layer in the second wafer;
removing the second etch stop layer to expose a third back surface layer of the second wafer;
removing the third back surface layer of the second wafer to expose a third etch stop layer in the second wafer;
removing the third etch stop layer to expose a second device layer in the second wafer;
applying a second protective mask on the second device layer in a second pattern to form a second masked portion and a second unmasked portion on the second device layer; and
etching the second unmasked portion of the second device layer to form a second ridge, wherein the etching the second unmasked portion of the second device layer to form the second ridge exposes the planarized surface, wherein the second ridge is formed in proximity to the first ridge on the planarized surface.

2. The wafer bonding method of claim 1, further comprising forming a first insulating layer on the first ridge and a second insulating layer on the second ridge.

3. The wafer bonding method of claim 1, wherein the bonding the first wafer to the planarized surface comprises:
positioning a front surface of the first wafer to face the planarized surface;
aligning the front surface of the first wafer with the planarized surface;
applying a first pressure to contact the front surface of the first wafer with the planarized surface at a center zone;
applying a second pressure to contact the front surface of the first wafer with the planarized surface at a first annular zone;
applying a third pressure to contact the front surface of the first wafer with the planarized surface at a second annular zone; and
exposing the contacted front surface of the first wafer and the planarized surface to a first heat treatment, wherein the exposing the contacted front surface of the first wafer and the planarized surface to the first heat treatment bonds the front surface of the first wafer to the planarized surface.

4. The wafer bonding method of claim 3, wherein the bonding the second wafer to the planarized surface comprises:
etching a front surface of the second wafer to form the pocket, wherein the pocket has a shape and dimensions to receive the first ridge;
positioning the front surface of the second wafer to face the planarized surface;
adjusting the position of the front surface of the second wafer to align the pocket formed on the second wafer to receive the first ridge on the planarized surface;
applying a fourth pressure to contact the front surface of the second wafer and the planarized surface at the center zone;
applying a fifth pressure to contact the front surface of the second wafer and the planarized surface at the first annular zone;
applying a sixth pressure to contact the front surface of the second wafer and the planarized surface at the second annular zone; and
exposing the contacted front surface of the second wafer and the planarized surface to a second heat treatment, wherein the exposing the contacted front surface of the second wafer and the planarized surface to the second heat treatment bonds the front surface of the second wafer to the planarized surface.

5. The wafer bonding method of claim 4, wherein the first and the second heat treatments comprise thermal annealing.

6. The wafer bonding method of claim 1, wherein the forming the patterned layer on the substrate layer further comprises:
forming the dielectric layer on the substrate layer;
forming a plurality of openings on the dielectric layer, wherein each of the plurality of the openings has a third pattern; and
depositing the conductive material to fill the plurality of the openings formed on the dielectric layer to form the patterned layer.

7. The wafer bonding method of claim 1, wherein the forming the patterned layer on the substrate layer further comprises:
depositing the conductive material on the substrate layer;
etching the conductive material deposited on the substrate layer in a third pattern with a plurality of openings to expose a top surface of the substrate layer; and
depositing the dielectric material to fill the plurality of the openings formed to expose the top surface of the surface layer to form the patterned layer.

8. The wafer bonding method of claim 1, wherein the first, the second and the third back surface layers are removed using backside exposure process.

9. The wafer bonding method of claim 1, wherein the first, the second and the third etch stop layers are removed using hydrogen flouride.

10. A wafer bonding method, said method comprising:
providing a substrate layer;
forming a dielectric layer on the substrate layer;
forming a plurality of openings on the dielectric layer, wherein each of the plurality of the openings has a first pattern;
depositing a conductive material to fill the plurality of the openings formed on the dielectric layer to form a patterned surface;
planarizing the patterned surface formed by the conductive material and the dielectric layer to form a planarized surface;
bonding a first wafer to the planarized surface;
removing a first back surface layer of the first wafer bonded to the planarized surface to expose a first etch stop layer in the first wafer;
removing the first etch stop layer to expose a first device layer in the first wafer;
applying a first protective mask on the first device layer in a second pattern to form a first masked portion and a first unmasked portion on the first device layer;
etching the first unmasked portion on the first device layer to form a first ridge, wherein the etching the first unmasked portion of the first device layer to form the first ridge exposes the planarized surface;
forming a first insulating layer on the first ridge;
bonding a second wafer to the planarized surface, wherein the bonding the second wafer to the planarized surface comprises:
etching a front surface of the second wafer to form a pocket, wherein the pocket has a shape and dimensions to receive the first ridge;
contacting the front surface of the second wafer with the planarized surface; and
exposing the contacted front surface of the second wafer and the planarized surface to a first heat treatment, wherein the exposing the contacted front surface of the second wafer and the planarized surface to the first heat treatment bonds the front surface of the second wafer to the planarized surface;
removing a second back surface layer of the second wafer to expose a second etch stop layer in the second wafer;
removing the second etch stop layer to expose a third back surface layer of the second wafer;
removing the third back surface layer of the second wafer to expose a third etch stop layer in the second wafer;
removing the third etch stop layer to expose a second device layer in the second wafer;
applying a second protective mask on the second device layer in a third pattern to form a second masked portion and a second unmasked portion on the second device layer;
etching the second unmasked portion of the second device layer to form a second ridge, wherein the etching the second unmasked portion of the second device layer exposes the planarized surface, wherein the second ridge is formed in proximity to the first ridge on the planarized surface; and
forming a second insulating layer on the second ridge.

11. The wafer bonding method of claim 10, wherein the bonding the first wafer to the planarized surface comprises:
positioning a front surface of the first wafer to face the planarized surface;
aligning the front surface of the first wafer with the planarized surface;
applying a first pressure to contact the front surface of the first wafer with the planarized surface at a center zone;
applying a second pressure to contact the front surface of the first wafer with the planarized surface at a first annular zone;
applying a third pressure to contact the front surface of the first wafer with the planarized surface at a second annular zone; and
exposing the contacted front surface of the first wafer and the planarized surface to a second heat treatment, wherein the exposing the contacted front surface of the first wafer and the planarized surface to the second heat treatment bonds the front surface of the first wafer to the planarized surface.

12. The wafer bonding method of claim 11, wherein the first and the second heat treatment comprises a thermal annealing.

13. The wafer bonding method of claim 11, wherein the contacting the front surface of the second wafer with the planarized surface comprises:
positioning the front surface of the second wafer to face the planarized surface;
adjusting the position of the front surface of the second wafer to align the pocket formed on the second wafer to receive the first ridge formed on the planarized surface;
applying a fourth pressure to contact the front surface of the second wafer and the planarized surface at the center zone;
applying a fifth pressure to contact the front surface of the second wafer and the planarized surface at the first annular zone; and
applying a sixth pressure to contact the front surface of the second wafer and the planarized surface at the second annular zone.

14. The wafer bonding method of claim 10, wherein the first, the second and the third back surface layers are removed using backside exposure process.

15. The wafer bonding method of claim 10, wherein the first, the second and the third etch stop layers are removed using hydrogen flouride.

16. A wafer bonding method, said method comprising:
forming a patterned layer on a substrate layer, wherein the patterned layer comprises a conductive material and a dielectric material;
planarizing the patterned layer formed by the conductive material and the dielectric material to form a planarized surface;
bonding a first wafer to the planarized surface, wherein the bonding the first wafer to the planarized surface comprises:
positioning a front surface of the first wafer to face the planarized surface;
aligning the front surface of the first wafer with the planarized surface;
contacting the front surface of the first wafer with the planarized surface; and
exposing the contacted front surface of the first wafer and the planarized surface to a first thermal annealing, wherein the exposing the contacted front surface of the first wafer and the planarized surface to the first thermal annealing bonds the front surface of the first wafer to the planarized surface;
removing a first back surface layer of the first wafer bonded to expose a first etch stop layer in the first wafer;
removing the first etch stop layer to expose a first device layer in the first wafer;
applying a first protective mask on the first device layer in a first pattern to form a first masked portion and a first unmasked portion on the first device layer;
etching the first unmasked portion on the first device layer to form a first ridge, wherein the etching the first unmasked portion of the first device layer to form the first ridge exposes the planarized surface;
forming a first insulating layer on the first ridge;
bonding a second wafer to the planarized surface, wherein the bonding the second wafer to the planarized surface comprises:
etching a front surface of the second wafer to form a pocket, wherein the pocket has a shape and dimensions to receive the first ridge, wherein the pocket is positioned on the front surface of the second wafer to substantially match the location of the first ridge formed on the planarized surface;
positioning the front surface of the second wafer to face the planarized surface;
adjusting the position of the front surface of the second wafer to align the pocket formed on the second wafer to receive the first ridge formed on the planarized surface;
contacting the front surface of the second wafer and the planarized surface; and
exposing the contacted front surface of the second wafer and the planarized surface to a second thermal annealing, wherein the exposing the contacted front surface of the second wafer and the planarized surface to the second thermal annealing bonds the front surface of the second wafer to the planarized surface;
removing a second back surface layer of the second wafer bonded to expose a second etch stop layer in the second wafer;
removing the second etch stop layer to expose a third back surface layer of the second wafer;
removing the third back surface layer of the second wafer to expose a third etch stop layer in the second wafer;
removing the third etch stop layer to expose a second device layer in the second wafer;
applying a second protective mask on the second device layer in a second pattern to form a second masked portion and a second unmasked portion on the second device layer;
etching the second unmasked portion of device layer to form a second ridge, wherein the etching the second unmasked portion of the second device layer exposes the planarized surface, wherein the second ridge is formed in proximity to the first ridge on the planarized surface; and
forming a second insulating layer on the second ridge.

17. The wafer bonding method of claim 16, wherein the forming the patterned layer on the substrate layer further comprises:
forming the dielectric layer on the substrate layer;
forming a plurality of openings on the dielectric layer, wherein each of the plurality of the openings has a third pattern; and
depositing the conductive material to fill the plurality of the openings formed on the dielectric layer to form the patterned layer.

18. The wafer bonding method of claim 16, wherein the forming the patterned layer on the substrate layer further comprises:
depositing the conductive material on the substrate;
etching the conductive material deposited on the substrate layer in a third pattern with a plurality of openings to expose a top surface of the substrate layer; and
depositing a dielectric material to fill the plurality of the openings formed to expose the top surface of the surface layer to form the patterned layer.

19. The wafer bonding method of claim 16, wherein the first, the second and the third back surface layers are removed using backside exposure process.

20. The wafer bonding method of claim 16, wherein the first, the second and the third etch stop layers are removed using hydrogen flouride.
